(19) United States
(12) Patent Application Publication
(10) Pub. No.: US 2010/0267237 A1
(43) Pub. Date: Oct. 21, 2010

(54) METHODS FOR FABRICATING FINFET SEMICONDUCTOR DEVICES USING ASHABLE SACRIFICIAL MANDRELS

(75) Inventors: Douglas J. Bonser, Hopewell Junction, NY (US); Frank S. Johnson, Wappinger Falls, NY (US); Catherine B. Labelle, Wappinger Falls, NY (US)

Correspondence Address: Ingrassia Fisher & Lorenz, P.C. (GF), 7010 E. Cochise Rd., Scottsdale, AZ, 85253, US

(73) Assignee: ADVANCED MICRO DEVICES, INC., Austin, TX (US)

(21) Appl. No.: 12/426,824

(22) Filed: Apr. 20, 2009

(51) Int. Cl. H01L 21/308

(52) U.S. Cl. 438/689; 257/E21.235

(57) ABSTRACT

Methods are provided for fabricating a semiconductor device on and in a semiconductor substrate. In accordance with an exemplary embodiment of the invention, one method comprises forming a sacrificial mandrel overlying the substrate, the sacrificial mandrel having sidewalls. Sidewall spacers are formed adjacent the sidewalls of the sacrificial mandrel. The sacrificial mandrel is removed using an ashing process, and the substrate is etched using the sidewall spacers as an etch mask after removal of the sacrificial mandrel.

### FIELD OF THE INVENTION

The present invention generally relates to methods for fabricating semiconductor devices, and more particularly relates to methods for fabricating FinFET semiconductor devices using ashable sacrificial mandrels.

### BACKGROUND OF THE INVENTION

Transistors, such as metal oxide semiconductor field-effect transistors (MOSFETs), are the core building blocks of the vast majority of semiconductor devices. Some semiconductor devices, such as high performance processor devices, can include millions of transistors. For such devices having a planar architecture and a single gate electrode, decreasing transistors size has traditionally been the primary means of fabricating ever increasing numbers of transistors on a single device chip.

Transistors having a non-planar architecture and more than one gate electrode have also been investigated as a means of increasing device density. A FinFET is a type of non-planar transistor that has one or more conductive fins that are raised above the substrate surface and extend between a source and drain region providing a channel for the device. Common methods of forming finned structures include the formation a sacrificial mandrel overlying a silicon substrate followed by the formation of thin spacers on the sidewalls of the mandrel. The mandrel then is subsequently selectively removed leaving the sidewall spacers standing intact on the surface of the substrate. Because of the support provided by the mandrel, spacers can be formed with a smaller base critical dimension (CD) and a larger aspect ratio (the ratio of the height of a feature to its smallest base CD) than would be possible using conventional lithographic means.

Typically, mandrels may be fabricated from an inorganic and/or dielectric material such as polycrystalline silicon or silicon oxide (SiOₓ) where x is a number greater than zero, silicon nitride (Si₃N₄), silicon oxynitride (SiON), or the like. Spacers generally comprise a dielectric material different in composition than that of the mandrel and chosen to facilitate high mandrel-to-spacer etch selectivity. Such highly selective etch processes help to maximize CD control of spacers and to minimize device defect levels by minimizing erosion of the sidewall spacers during the mandrel etch. Certain wet etchants such as, for example, hydrochloric acid (HCl) solutions offer improved etch selectivity compared with dry etch processes in the removal of mandrel materials such as polycrystalline silicon. However, wet etchants can exacerbate spacer collapse and increase defect count because of the viscous and capillary forces they generate.

Accordingly, it is desirable to provide methods for fabricating FinFET transistor devices using ashable sacrificial mandrels. Further, other desirable features and characteristics of the present invention will become apparent from the subsequent detailed description of the invention and the appended claims, taken in conjunction with the accompanying drawings and this background of the invention.

### BRIEF SUMMARY OF THE INVENTION

Methods are provided for fabricating a semiconductor device on and in a semiconductor substrate. In accordance with an exemplary embodiment of the invention, one method comprises forming a sacrificial mandrel overlying the substrate wherein the sacrificial mandrel has sidewalls. Sidewall spacers are formed adjacent the sidewalls of the sacrificial mandrel. The sacrificial mandrel is removed using an ashing process, and the substrate is etched using the sidewall spacers as an etch mask after removal of the sacrificial mandrel.

A method is provided for fabricating a semiconductor device on and in a semiconductor substrate in accordance with another exemplary embodiment of the invention. The method comprises the steps of forming an ashable material layer overlying the substrate and patterning the ashable material layer to form an ashable mandrel having sidewalls. Sidewall spacers are formed adjacent the sidewalls of the ashable mandrel, and the ashable mandrel is removed using an ashing process having an etch rate of the ashable mandrel relative to the sidewall spacers of at least about 50:1. The substrate is etched using the sidewall spacers as an etch mask after removal of the ashable mandrel.

### BRIEF DESCRIPTION OF THE DRAWINGS

The present invention will hereinafter be described in conjunction with the following drawing figures, wherein like numerals denote like elements, and wherein:

FIGS. 1-5 illustrate schematically, in cross-section, methods for fabricating a finned semiconductor device using ashable sacrificial mandrels in accordance with exemplary embodiments of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

The various embodiments of the present invention describe methods for fabricating FinFET transistors using ashable sacrificial mandrels. Ashable materials such as, for example, amorphous carbon are substituted for conventional inorganic sacrificial mandrel materials such as SiOₓ, Si₃N₄, polycrystalline silicon, SiON, and the like, and are removed following spacer formation using a highly selective oxygen-based (O₂) plasma ashing process. In accordance with one embodiment, the ashing process removes the ashable sacrificial mandrel with at least a 50:1 etch selectivity, or with an etch rate that is at least 50 times faster than the etch rate for dielectric/inorganic spacer materials. Materials suitable as ashable sacrificial mandrels also have physical properties that are sufficient to withstand exposure to etch processes needed for mandrel formation, and the subsequent thermal processing budget (time and temperature) associated with deposition and etch processes needed for the formation of sidewall spacers.

FIGS. 1-5 illustrate schematically, in cross section, methods for forming a FinFET transistor device 100 using an ashable sacrificial mandrel, in accordance with various exemplary embodiments of the invention. While the fabrication of portions of one FinFET transistor is illustrated, it will be appreciated that the method depicted in FIGS. 1-5 can be used to fabricate any number of such transistors. Various steps in the manufacture of semiconductor device components are well known and so, in the interest of brevity, many conventional steps will only be mentioned briefly herein or will be omitted entirely without providing the well known process details.

Referring to FIG. 1, the method begins by providing a semiconductor substrate 110 on and in which FinFET semiconductor device 100 will subsequently be formed. The semiconductor substrate can be silicon, germanium, a III-V material such as gallium arsenide, or other semiconductor material. Semiconductor substrate 110 will hereinafter be referred to for convenience, but without limitation, as a silicon substrate. The term “silicon substrate” is used herein to encompass the relatively pure silicon materials typically used in the semiconductor industry as well as silicon admixed with other elements such as germanium, carbon, and the like. The silicon substrate may be a bulk silicon wafer or, as illustrated, may be a thin layer of silicon 106 on an insulating layer 104 (commonly know as silicon-on-insulator, or SOI) that, in turn, is supported by a carrier wafer 102.

An ashable material layer 116 is formed overlying thin silicon layer 106. Ashable material layer 116 may comprise any suitable material that is removable using a dry, plasma, O₂-based ashing process. As will be described in further detail below, layer 116 will be patterned to form mandrels and therefore should have suitable thermal properties to withstand such patterning. Sidewall spacers will also be formed on the mandrels and therefore a material suited for use as layer 116 can also withstand the additional subsequent deposition and etch processes used to form these spacers. In one embodiment, ashable material layer 116 comprises amorphous carbon (a-C). As used herein, the term amorphous carbon also includes hydrogenated amorphous carbon (a-C:H) and further includes any microstructure such as, for example, diamond-like amorphous carbon (DLC), polymer-like amorphous carbon (PLC), or any combination of these microstructures. Further, the term amorphous carbon may be used without limitation as to the percentage of the material having a particular polycrystalline microstructure. The DLC microstructure provides a film with a higher density and hardness and a lower hydrogen (H) content than a PLC microstructure. Amorphous carbon may be deposited using a suitable chemical vapor deposition (CVD) or plasma enhanced chemical vapor deposition (PECVD) process based on a hydrocarbon gas or mixture of hydrocarbon gases such as, for example, acetylene (C₂H₂), propylene (C₃H₆), or the like, and may also include hydrogen (H₂). Deposition of a-C films may be performed using, for example, the ashable hard mask (AHM) process (available from Novellus Systems, Inc., San Jose, Calif.) run on the Vector® Express PECVD platform, or the Producer PECVD platform (available from Applied Materials, Inc., Santa Clara, Calif.).

In another embodiment, ashable material layer 116 may be a suitable thermoplastic polymeric material such as, for example, a thermoplastic polyimide, or a thermosetting polymeric material such as, for example, a thermosetting polyimide, an epoxy, or the like having adequate thermal properties as described above. Such a polymeric material may be applied in any manner, and preferably in a dissolved state using, for example, a suitable spin-on coating and post-application bake sequence. Because sidewall spacers will be subsequently formed adjacent the sidewalls of sacrificial mandrels made from ashable material layer 116, the thickness of layer 116 will be selected based, at least in part, upon the desired height of these spacers. The spacer height, in turn, will depend upon the etch selectivity of the subsequent pattern transfer of the spacers into the substrate to form fin structures in conjunction with the desired fin height. Ashable material layer 116 may therefore have any thickness consistent with these considerations in conjunction with the overall design of device 100. In one embodiment, ashable material layer 116 has a thickness of from about 100 nanometers (nm) to about 1 micron (μm). A suitable patterned soft mask 124 then is formed overlying ashable material layer 116 using conventional photoresist and lithography processes.

Ashable material layer 116 is anisotropically etched using soft mask 124 as an etch mask to form sacrificial mandrels 132, as illustrated in FIG. 2. This etch may be performed using a suitable plasma or reactive ion etch (RIE) process based upon ozone (O₃), O₂, ammonia (NH₃), or a mixture of nitrogen (N₂) and H₂. Depending on the selectivity of this etch process to photoresist, a hard mask (not shown) comprising, for example, silicon nitride, silicon oxynitride, or silicon oxide, may optionally be interposed between ashable material layer 116 and soft mask 124 and patterned using mask 124. The patterned hard mask along with the remainder of soft mask 124 are then used as masks for patterning ashable material layer 116. Any remaining soft mask 124 and/or hard mask is then removed.

Next, a sidewall spacer layer 128 comprising an inorganic dielectric material such as, for example, silicon nitride, silicon oxynitride, or preferably silicon oxide is conformally blanket-deposited overlying the surface of device 100 including sacrificial mandrels 132. Sidewall spacer layer 128 may be deposited, for example, by a PECVD process using silane (SiH₄) and either nitrous oxide (N₂O) or O₂ to form a silicon oxide layer, or by using SiH₄ and NH₃ or N₂ in the presence of an argon (Ar) plasma to form a silicon nitride layer. Layer 128 may also be deposited using low pressure chemical vapor deposition (LPCVD) using tetraethyl orthosilicate (TEOS: Si(OC₂H₅)₄), or dichlorosilane (SiH₂Cl₂) and N₂O to form a silicon oxide layer. In one embodiment, sidewall spacer layer 128 has a thickness of from about 100 nm to about 1 μm. As described in greater detail below, sidewall spacer layer 128 will form sidewall spacers that will be used as an etch mask for etching thin silicon layer 106 to form fin structures. The width, or smallest base CD of these spacers is a significant factor in defining the width of the final fin structures, and is determined, at least in part, by the thickness of layer 128.

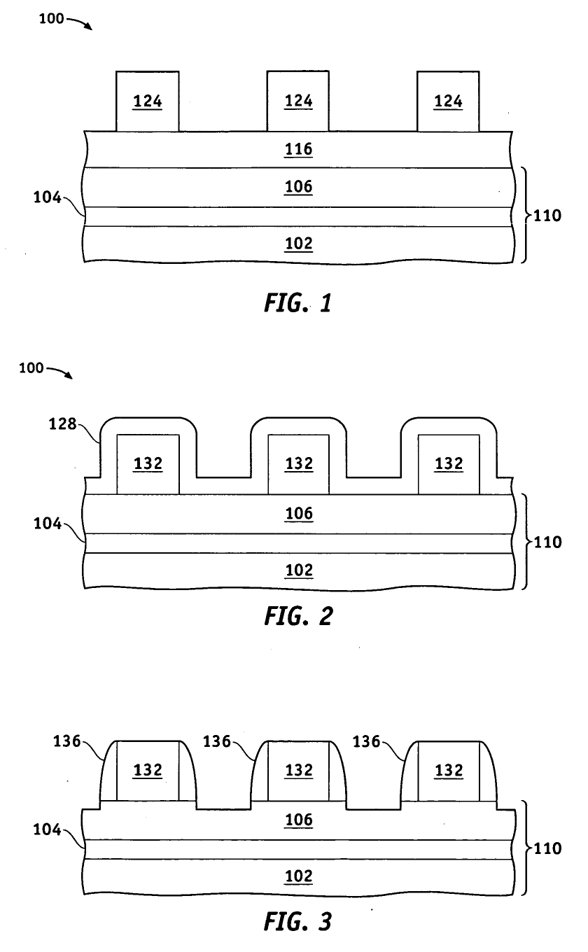

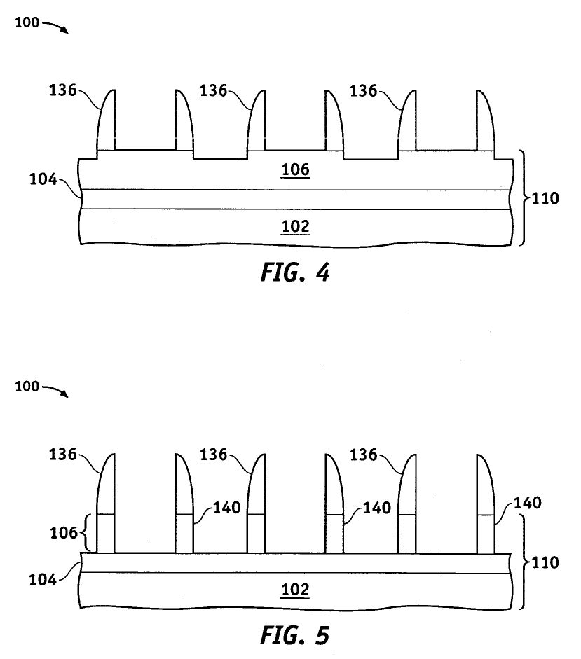

The method continues with the anisotropic etch of sidewall spacer layer 128 to form sidewall spacers 136 on the sidewalls of sacrificial mandrels 132, as illustrated in FIG. 3. This etch may be performed by, for example, an RIE process using chemistries based upon carbon trifluoride/oxygen (CHF₃/O₂) to etch silicon nitride, and CHF₃ or carbon tetrafluoride (CF₄) to etch silicon oxynitride or silicon oxide. Depending on the selectivity of this etch between sidewall spacer layer 128 and thin silicon layer 106, a portion of layer 106 may also be removed. Next, sacrificial mandrels 132 are removed, as illustrated in FIG. 4, using a suitable O₂-based, dry plasma ashing process highly selective to sacrificial mandrels 132 such that thin silicon layer 106 and sidewall spacers 136 are only negligibly eroded. In one embodiment, ashing of sacrificial mandrels 132 is performed with a selectivity of about 50 or greater relative to sidewall spacers 136. That is, during the ashing process, the consumption or etch rate of mandrels 132 is at least about 50 times that of spacers 136. Following the removal of sacrificial mandrels 132, sidewall spacers 136 may be used as etch masks for the formation of fin structures 140 etched into thin silicon layer 106 to insulating layer 104 as required for fabrication of FinFET device 100, as illustrated in FIG. 5. The remainder of spacers 136 then may be removed using any suitable wet or preferably dry etch process selective to spacers 136 to avoid erosion of fin structures 140.

Accordingly, methods have been provided for the fabrication of FinFET transistor devices using ashable sacrificial mandrels. Such mandrels are formed by the deposition and patterning of a layer of an ashable material such as amorphous carbon overlying a semiconductor substrate. Sidewall spacers comprising, for example, a dielectric material are formed on the sidewalls of the sacrificial mandrels followed by the removal of the mandrels using a dry, plasma, O₂-based ashing process. The ashing process removes the ashable sacrificial mandrel material with a high level of selectivity relative to surrounding spacer and substrate materials. Because of the high etch selectivity, spacer materials may be chosen based upon their etch selectivity as hard etch masks to the substrate material, rather than based upon selectivity to both substrate and mandrel materials. In addition, removal of the mandrel in a highly selective manner reduces spacer erosion during this process enabling improved CD control of these features. Further, defects that might otherwise be caused by viscous and capillary forces associated with wet etchants are avoided by using a dry ashing process. Accordingly, fabrication of FinFET transistors having fin structures with improved CD control and fewer defects is enabled via a processing sequence that may be easily incorporated into a typical semiconductor fabrication line.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method of fabricating a semiconductor device on and in a semiconductor substrate, the method comprising the steps of:
forming a sacrificial mandrel overlying the substrate, the sacrificial mandrel having sidewalls;
forming sidewall spacers adjacent the sidewalls of the sacrificial mandrel;
removing the sacrificial mandrel using an ashing process; and
etching the substrate using the sidewall spacers as an etch mask after removal of the sacrificial mandrel.

2. The method of claim 1, wherein the step of forming a sacrificial mandrel comprises:
forming an ashable material layer overlying the substrate; and
patterning the ashable material layer to form the sacrificial mandrel.

3. The method of claim 1, wherein the step of forming a sacrificial mandrel comprises forming a sacrificial amorphous carbon mandrel.

4. The method of claim 3, wherein the step of forming a sacrificial amorphous carbon mandrel comprises the step of forming a sacrificial diamond-like amorphous carbon mandrel.

5. The method of claim 3, wherein the step of forming a sacrificial amorphous carbon mandrel comprises the step of forming a sacrificial polymer-like amorphous carbon mandrel.

6. The method of claim 1, wherein the step of forming a sacrificial mandrel comprises the step of forming a sacrificial ashable polymeric mandrel.

7. The method of claim 6, wherein the step of forming a sacrificial ashable polymeric mandrel comprises forming a sacrificial ashable thermoplastic polymeric mandrel.

8. The method of claim 7, wherein the step of forming a sacrificial ashable thermoplastic polymeric mandrel comprises forming a sacrificial ashable thermoplastic polyimide mandrel.

9. The method of claim 6, wherein the step of forming a sacrificial ashable polymeric mandrel comprises forming a sacrificial ashable thermosetting polymeric mandrel.

10. The method of claim 9, wherein the step of forming a sacrificial ashable thermosetting polymeric mandrel comprises forming a sacrificial ashable epoxy mandrel.

11. The method of claim 9, wherein the step of forming a sacrificial ashable thermosetting polymeric mandrel comprises forming a sacrificial ashable thermosetting polyimide mandrel.

12. A method of fabricating a semiconductor device on and in a semiconductor substrate, the method comprising the steps of:
forming an ashable material layer overlying the substrate;
patterning the ashable material layer to form an ashable mandrel, the ashable mandrel having sidewalls;
forming sidewall spacers adjacent the sidewalls of the ashable mandrel;
removing the ashable mandrel using an ashing process having an etch rate of the ashable mandrel relative to the sidewall spacers of at least about 50:1; and
etching the substrate using the sidewall spacers as an etch mask after removal of the ashable mandrel.

13. The method of claim 12, wherein the step of forming an ashable material layer comprises forming an ashable amorphous carbon layer.

14. The method of claim 13, wherein the step of forming an ashable amorphous carbon layer comprises forming an ashable diamond-like amorphous carbon layer.

15. The method of claim 13, wherein the step of forming an ashable amorphous carbon layer comprises forming an ashable polymer-like amorphous carbon layer.

16. The method of claim 12, wherein the step of forming an ashable material layer comprises forming an ashable polymeric layer.

17. The method of claim 16, wherein the step of forming an ashable polymeric layer comprises forming an ashable thermoplastic polymeric layer.

18. The method of claim 17, wherein the step of forming an ashable thermoplastic polymeric layer comprises forming an ashable thermoplastic polyimide layer.

19. The method of claim 16, wherein the step of forming an ashable polymeric layer comprises forming an ashable thermosetting polymeric layer.

20. The method of claim 19, wherein the step of forming an ashable thermosetting polymeric layer comprises forming an ashable thermosetting polyimide layer.
